(19) United States
(12) Patent Application Publication
(10) Pub. No.: US 2015/0214441 A1
(43) Pub. Date: Jul. 30, 2015

(54) LIGHT EMITTING DIODE PACKAGE AND ILLUMINATING DEVICE

(71) Applicant: Chunghwa Picture Tubes, LTD., Taoyuan (TW)

(72) Inventors: Kuan-Yu Chen, Taoyuan County (TW); Tzu-Pin Lin, Taoyuan County (TW)

(73) Assignee: Chunghwa Picture Tubes, LTD., Taoyuan (TW)

(21) Appl. No.: 14/205,308

(22) Filed: Mar. 11, 2014

(30) Foreign Application Priority Data
Jan. 27, 2014 (TW) 103201709

(51) Int. Cl. H01L 33/50; H01L 33/52; H01L 33/62; H01L 27/15

(52) U.S. Cl. CPC H01L 33/502; H01L 27/15; H01L 33/52; H01L 33/62

(57) ABSTRACT

A LED package including a transparent substrate, at least one LED chip, a first sealing layer and a second sealing layer is provided. The transparent substrate has a first surface and a second surface opposite the first surface. The LED chip is disposed on the first surface of the transparent substrate. The first sealing layer is disposed on the first surface of the transparent substrate and covers the LED chip. The second sealing layer is disposed on the second surface of the transparent substrate and overlaps with the LED chip in a direction perpendicular to the transparent substrate. The LED chip is used to emit a light beam. A portion of the light beam exits the LED package by passing through the transparent substrate and the second sealing layer. Moreover, an illuminating device including the aforementioned LED package is also provided.

### CROSS-REFERENCE TO RELATED APPLICATION

This application claims the priority benefit of Taiwan application serial no. 103201709, filed on Jan. 27, 2014. The entirety of the above-mentioned patent application is hereby incorporated by reference herein and made a part of this specification.

### BACKGROUND OF THE INVENTION

1. Field of the Invention

The present invention generally relates to an optoelectronic device, in particular, to a LED (Light emitting diode) package and an illuminating device.

2. Description of Related Art

The working principle of a LED chip is as below: the electrons and the holes adjacent to the boundary between the first type semiconductor layer and the second type semiconductor layer of the LED chip recombine and then the LED chip emits a light beam by providing a current to the LED chip. Different from the traditional light emitting methods such as the filament heating or electric discharge, the light emitting method of the LED chip belongs to cold emitting; therefore, the advantage of the LED chip is long lifetime. Besides, the LED chip further includes other advantages, such as fast response, small volume, low power consumption, low pollution, and etc. As a result, the LED chip is widely used in various applications.

In order to increase the longevity and reliability of the LED chip, a package process is implemented to form a LED package after the LED chip is completed. FIG. 1 is a schematic of a known LED package. Please refer to FIG. 1, generally, a complete LED chip 10 is fixed in a cup 20, which is known as a die bonding process. Two electrodes 12 of the LED chip 10 are electrically coupled to two conductive pins 30. Then, a LED package 50 is completed after a sealing material 40 having a phosphor powder is refilled into the cup 20 to cover the LED chip 10. However, a portion of light beam L emitting from the boundary 15 between the first type semiconductor 14 and the second type semiconductor 16 of the LED chip 10 is blocked by the conductive pins 30 and the cup 20 because the conductive pins 30 and the cup 20 are non-transparent. As a result, the light extraction efficiency of the LED package 50 is reduced.

### SUMMARY OF THE INVENTION

A LED package of the invention is provided, and its light extraction efficiency is high.

An illuminating device of the invention is provided, and its light extraction efficiency is high.

A LED package of the invention includes a transparent substrate, at least one LED chip, a first sealing layer and a second sealing layer is provided. The transparent substrate has a first surface and a second surface opposite to the first surface. The LED chip is disposed on the first surface of the transparent substrate. The first sealing layer is disposed on the first surface of the transparent substrate and covers the LED chip. The second sealing layer is disposed on the second surface of the transparent substrate and overlaps with the LED chip in a direction perpendicular to the transparent substrate. The LED chip is used to emit a light beam. A portion of the light beam exits the LED package by passing through the transparent substrate and the second sealing layer.

An illuminating device of the invention includes a lampshade, a lamp holder enclosing an accommodating space with the lampshade and the aforementioned LED package. The LED package is disposed in the accommodating space.

In an embodiment of the invention, the aforementioned transparent substrate is a glass substrate.

In an embodiment of the invention, each of the aforementioned LED chip includes a first semiconductor layer, a second semiconductor layer connected to the first semiconductor layer, a first electrode disposed on the first semiconductor layer and a second electrode disposed on the second semiconductor layer and spaced from the first electrode.

In an embodiment of the invention, at least one aforementioned LED chip is a plurality of LED chips. The transparent substrate further comprises a first power-supply electrode and a second power-supply electrode spaced from the first power-supply electrode. The LED chips are arranged in at least one LED chip row from the first power-supply electrode to the second power-supply electrode. The LED package further comprises a plurality of wires. The second electrode of each LED chip is electrically coupled to the first electrode of the adjacent LED chip by a wire except one LED chip closest to the first power-supply electrode. The first electrode of the LED chip closest to the first power-supply electrode is electrically coupled to the first power-supply electrode by a wire. The second electrode of the LED chip closest to the second power-supply electrode is electrically coupled to the second power-supply electrode by a wire. In a word, a plurality of LED chips in the same LED chip row are electrically coupled to each other in series.

In an embodiment of the invention, the aforementioned LED chips are arranged in a plurality of LED chip rows. The LED chip rows are electrically coupled to each other in parallel.

In an embodiment of the invention, each of the aforementioned LED chip has a bottom surface facing the transparent substrate, a top surface opposite to the bottom surface and a side surface connected the bottom surface and the top surface. The LED chips are spaced from each other.

In an embodiment of the invention, the aforementioned first sealing layer includes a first sealing material and a first phosphor powder mixed into the first sealing material, and the second sealing layer includes a second sealing material and a second phosphor powder mixed into the second sealing material.

In an embodiment of the invention, a portion of the aforementioned light beam is transformed into a second light having a different color from the light beam by passing through the second phosphor powder of the second sealing layer, and another portion of the light beam is transformed into a first light having a different color from the light beam by passing through the first phosphor powder of the first sealing layer.

In an embodiment of the invention, the aforementioned first light and second light are white light.

In summary, a LED package and an illuminating device of an embodiment of the invention package the LED chip using the transparent substrate. Besides the light beams emitting from the top surface and the side surface of the LED chip transmit out of the LED package, the light beam emitting from the bottom surface of the LED chip passes through the transparent substrate and is used by the user. Consequently, the light extraction efficiency of the LED package and the illuminating device is increased.

To make the above features and advantages of the present invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1 is a schematic showing a known LED package.

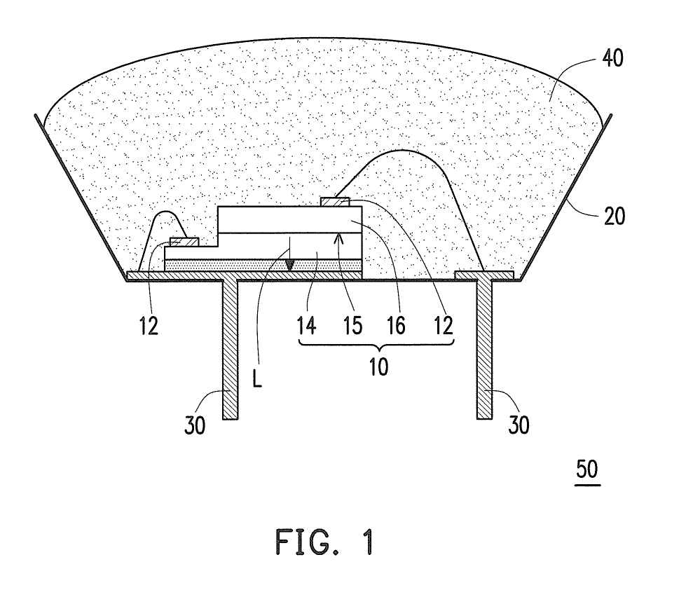

FIG. 2A is a top view of a schematic showing a LED package of an embodiment of an invention.

FIG. 2B is a cross-sectional view of a schematic showing the LED package along line A-A′ in FIG. 2A.

FIG. 3 is a schematic showing an illuminating device of an embodiment of an invention.

### DESCRIPTION OF THE EMBODIMENTS

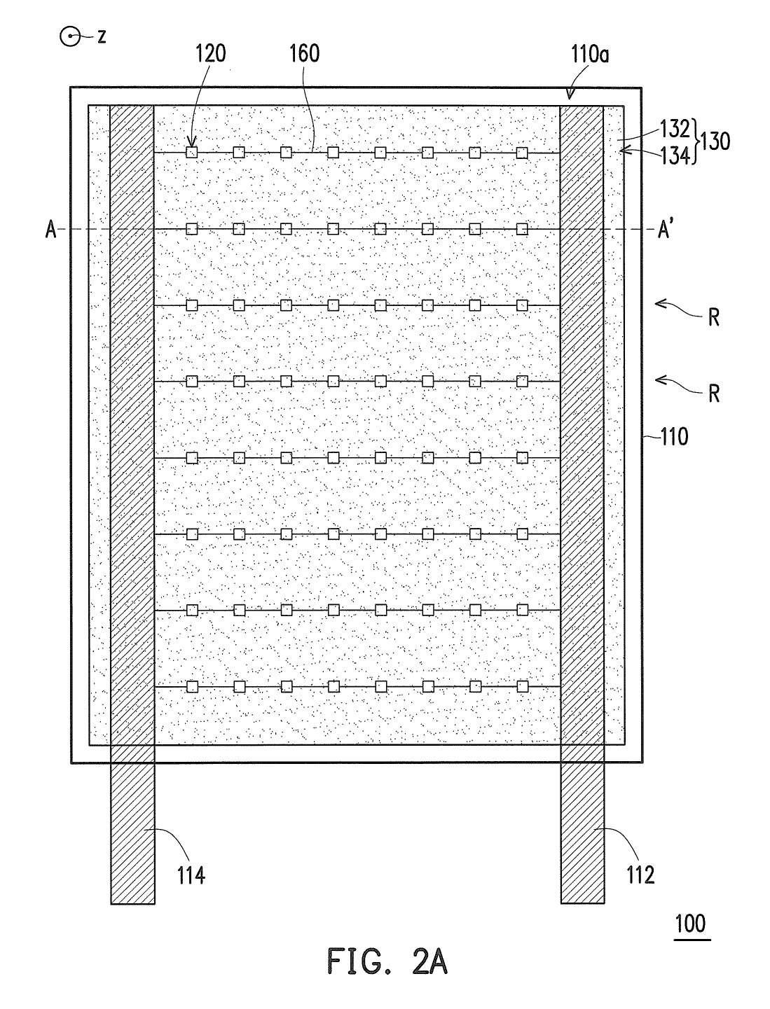

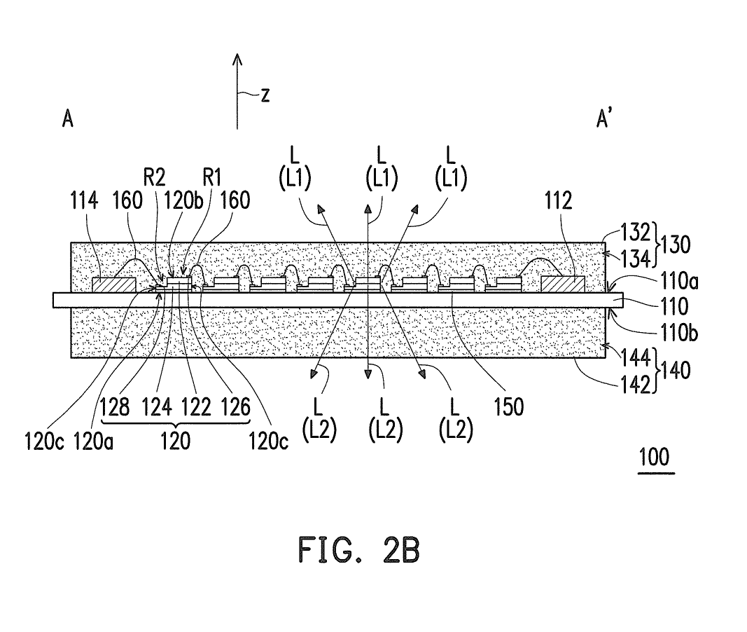

FIG. 2A is a top view of a schematic showing a LED package of an embodiment of an invention. FIG. 2B is a cross-sectional view of a schematic showing the LED package along line A-A′ in FIG. 2A. Please refer to FIG. 2A and FIG. 2B, a LED package 100 includes a transparent substrate 110, at least one LED chip 120, a first sealing layer 130 and a second sealing layer 140. The transparent substrate 110 has a first surface 110a and a second surface 110b opposite to each other. In the embodiment, the first surface 110a and the second surface 110b may be two planar surfaces parallel to each other. However, the invention is not limited thereto. In other embodiments, the first surface 110a and the second surfaces 110b may be convex surfaces, concave surfaces, planar surfaces or the combinations thereof. The material of the transparent substrate 110 is preferred to be high transparency, such as glass, but the invention is not limited thereto. In other embodiments, the transparent substrate 110 may be other suitable transparent material.

At least one LED chip 120 is disposed on the first surface 110a of the transparent substrate 110. In the embodiment, at least one LED chip 120 may be fixed on the first surface 110a of the transparent substrate 110 by a transparent glue 150. However, the invention is not limited to it. In other embodiments, the LED chip 120 may be fixed on the first surface 110a of the transparent substrate 110 by other suitable methods. In the embodiment, at least one LED chip 120 may be a plurality of LED chips 120, and the LED chips 120 may be arranged on the transparent substrate 110 in a matrix. However, the invention is not limited thereto. The quantity and the arrangement of the LED chips 120 are designed properly according to the real demand.

As showed in FIG. 2B, in the embodiment, each of the LED chips 120 includes a first semiconductor layer 122 (such as n-type semiconductor layer), a second semiconductor layer 124 (such as p-type semiconductor layer) connected to the first semiconductor layer 122, a first electrode 126 disposed on the first semiconductor layer 122 and a second electrode 128 disposed on the second semiconductor layer 124 and spaced from the first electrode 126. More specifically, the second semiconductor layer 124 is disposed between the first semiconductor layer 122 and the transparent substrate 110. The second semiconductor layer 124 has a region R2 exposed by the first semiconductor layer 122. The second electrode 128 is disposed on the region R2. The first semiconductor layer 122 has a region R1 overlapping with the second semiconductor layer 124. The first electrode 126 is disposed on the region R1. Each of the LED chips 120 has a bottom surface 120a facing the transparent substrate 110, a top surface 120b opposite to the bottom surface 120a and a side surface 120c connected the bottom surface 120a and the top surface 120b. In the embodiment, the first electrode 126 and the second electrode 128 are disposed on the top surface 120b. However, it should be noted that the type of the LED chip of the invention is not limited to this paragraph and FIG. 2A and FIG. 2B. In other embodiments, the LED chip may be another suitable type.

Please referring to FIG. 2A and FIG. 2B again, in the embodiment, the transparent substrate 110 further includes a first power-supply electrode 112 and a second power-supply electrode 114 spaced from the first power-supply electrode 112. The first electrode 126 and the second electrode 128 of each of the LED chips 120 are electrically coupled to the first power-supply electrode 112 and the second power-supply electrode 114 respectively. In detail, the LED package 100 may selectively include a plurality of wires 160. The wires 160 electrically connects the first electrode 126 of each of the LED chips 120 to the first power-supply electrode 112 and connects the second electrode 128 of each of the LED chip 120 to the second power-supply electrode 114. In the embodiment, the LED chips 120 electrically connects the first power-supply electrode 112 and the second power-supply electrode 114 by wire bonding. However, the invention is not limited thereto. In other embodiments, the LED chip 120 electrically connects the first power-supply electrode 112 and the second power-supply electrode 114 by the process of flip chip package or other suitable methods.

In the embodiment, as showed in FIG. 2A, a plurality of LED chips 120 are arranged in a plurality of LED chip rows R. The LED chips 120 of each of the LED chip rows R are arranged from the first power-supply electrode 112 to the second power-supply electrode 114. The LED package 100 further includes a plurality of wires 160. As showed in FIG. 2B, a portion of the second electrode 128 of each of the LED chips 120 is electrically coupled to the first electrode 126 of the adjacent LED chip 120 by a wire 160 except one LED chip 120 closest to the first power-supply electrode 112 in the LED chip row R. The first electrode 126 of the LED chip 120 closest to the first power-supply electrode 112 is electrically coupled to the first power-supply electrode 112 by a wire 160. The second electrode 128 of the LED chip 120 closest to the second power-supply electrode 114 is electrically coupled to the second power-supply electrode 114 by a wire 160. In brief, a plurality of LED chips in the same LED chip row are electrically coupled to each other in series. Besides, as showed in FIG. 2A, a plurality of LED chip rows are electrically coupled to each other in parallel. However, the invention is not limited thereto. In other embodiments, a plurality of LED chips 120 are electrically coupled by other suitable methods.

The first sealing layer 130 is disposed on the first surface 110a of the transparent substrate 110 and covers the LED chip 120. More specifically, in the embodiment, the first sealing layer 130 covers the first surface 110a of the transparent substrate 110 fully and covers the top surface 120b and side surface 120c of each LED chip 120 and the wires 160. The first sealing layer 130 includes a first sealing material 132 and a first phosphor powder 134 mixed into the first sealing material 132. In the embodiment, the first phosphor powder 134, for example, is yellow phosphorus, but the invention is not limited thereto.

When the first power-supply electrode 112 and the second power-supply electrode 114 provide a current to the first electrode 126 and the second electrode 128 of each of the LED chips 120, each of the LED chips 120 emits a light beam L. In the embodiment, the light beam L before passing through the first sealing layer 130 or the second sealing layer 140, for example, is a blue light. A portion of the light beam L1 is transformed into a first light having a different color, such as white light, from the light beam L by passing through the first phosphor powder 134 of the first sealing layer 130.

The second sealing layer 140 is disposed on the second surface 110b of the transparent substrate 110 and overlaps with the LED chip 120 in a direction z perpendicular to the transparent substrate 110. More specifically, the second sealing layer 140 may cover the second surface 110b of the transparent substrate 110 fully, and the region on the second surface 110b of the transparent substrate 110 covered by the second sealing layer 140 may cover the bottom surface 120a of each of the LED chips 120 fully. In the embodiment, the second sealing layer 140 includes a second sealing material 142 and a second phosphor powder 144 mixed into the second sealing material 142. In the embodiment, the second phosphor powder 144, for example, is yellow phosphorus, but the invention is not limited thereto.

When the first power-supply electrode 112 and the second power-supply electrode 114 provide a current to the first electrode 126 and the second electrode 128 of each of the LED chips 120, each of the LED chips 120 emits a light beam L. In the embodiment, the light beam L before passing through the first sealing layer 130 or the second sealing layer 140, for example, is a blue light. A portion of the light beam L2 is transformed into a second light having a different color, such as white light, from the light beam L by passing through the second phosphor powder 144 of the second sealing layer 140.

Note that the color of the aforementioned light beam L before passing through the first sealing layer 130 or the second sealing layer 140, the material of the first phosphor powder 134, and the material of the second phosphor powder 144 are exemplary to explain the invention, and the invention is not limited thereto. The color of the light beam L before passing through the first sealing layer 130 or the second sealing layer 140, the material of the first phosphor powder 134, and the material of the second phosphor powder 144 are determined by the final lighting type presented by the LED package 100. More specifically, in other embodiments, if the LED package shows multiple colors, the first phosphor powder 134 and the second phosphor powder 144 may be different material.

It should be noted that when LED chip 120 is packaged using the transparent substrate 110, the light beam L emitting from the bottom surface 120a of the LED chip 120 transmits out of the LED package 100 by passing through the transparent substrate 110 and the second sealing layer 140 and is used by the user except the light beam L emitting from the top surface 120b and side surface 120c of the LED chip 120. In other word, the light extraction efficiency of the LED package 100 is improved by packaging the LED chip 120 using the transparent substrate 110.

Besides, the LED package 100 of the invention uses a plurality of cheap LED chips 120 as a light source. A plurality of LED chips 120 are space from each other, and any one of the LED chips 120 exposes the bottom surface 120a, the top surface 120b and the side surface 120c of each of other LED chips 120. Therefore, the total emitting area of the light source maximizes. The LED package 100 with low cost and high luminance is realized.

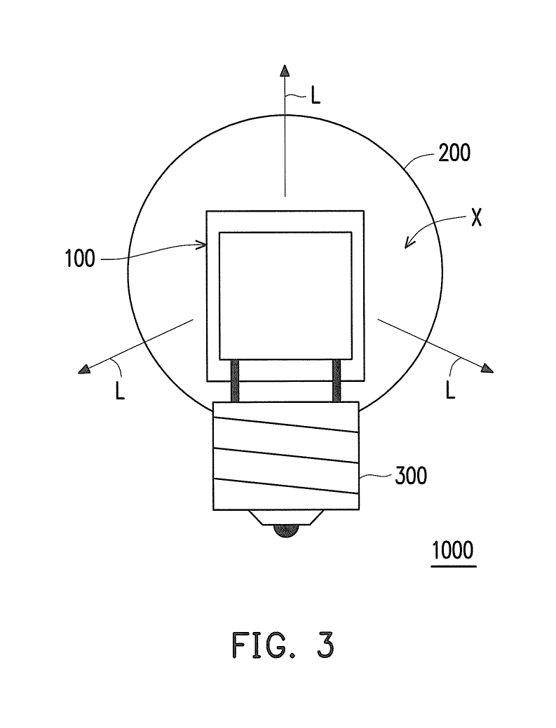

FIG. 3 is a schematic showing an illuminating device of an embodiment of an invention. Please refer to FIG. 3, an illuminating device 1000 includes a lampshade 200, a lamp holder 300 and a LED package 100. The lampshade 200 and the lamp holder 300 enclose an accommodating space X. The LED package 100 is disposed in the accommodating space X. Because the light beam L emitting from the top surface 120b, side surface 120c and the bottom surface 120a of the LED chip 120 transmits out of the LED package 100, the illuminating device 1000 using the LED package 100 realizes a light source emitting light beams toward every direction.

To sum up, in the LED package and the illuminating device of an embodiment of the invention, the LED chip is packaged using the transparent substrate. The light beam emitting from the bottom surface of the LED chip passes through the transparent substrate and is used by the user except the light beams emitting from the top surface and the side surface of the LED chip. Consequently, the light extraction efficiency of the LED package and the illuminating device is increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A light emitting diode package comprising:
a transparent substrate having a first surface and a second surface opposite to each other;
at least one LED chip disposed on the first surface of the transparent substrate;
a first sealing layer disposed on the first surface of the transparent substrate and covering the LED chip; and
a second sealing layer disposed on the second surface of the transparent substrate and overlapping with the LED chip in a direction perpendicular to the transparent substrate, wherein the LED chip is used to emit a light beam, and a portion of the light beam exits the LED package by passing through the transparent substrate and the second sealing layer.

2. The light emitting diode package according to claim 1, wherein the transparent substrate is a glass substrate.

3. The light emitting diode package according to claim 1, wherein the at least one LED chip is a plurality of LED chips, each of the LED chips includes a first semiconductor layer, a second semiconductor layer connected to the first semiconductor layer, a first electrode disposed on the first semiconductor layer and a second electrode disposed on the second semiconductor layer and spaced from the first electrode.

4. The light emitting diode package according to claim 3, wherein the transparent substrate further comprises a first power-supply electrode and a second power-supply electrode spaced from the first power-supply electrode, the LED chips arranged in at least one LED chip row from the first power-supply electrode to the second power-supply electrode, the LED package further comprises a plurality of wires, a portion of the second electrode of each of the LED chips electrically coupled to the first electrode of the adjacent LED chip by one of the wires except the LED chip closest to the first power-supply electrode, the first electrode of the LED chip closest to the first power-supply electrode electrically coupled to the first power-supply electrode by another of the wires, the second electrode of the LED chip closest to the second power-supply electrode electrically coupled to the second power-supply electrode by yet another of the wires.

5. The light emitting diode package according to claim 4, wherein the LED chips are arranged in a plurality of LED chip rows, the LED chip rows electrically coupled to each other in parallel.

6. The light emitting diode package according to claim 1, wherein each of the LED chips has a bottom surface facing the transparent substrate, a top surface opposite to the bottom surface, and a side surface connected the bottom surface and the top surface, the LED chips spaces from each other.

7. The light emitting diode package according to claim 1, wherein the first sealing layer includes a first sealing material and a first phosphor powder mixed into the first sealing material, and the second sealing layer includes a second sealing material and a second phosphor powder mixed into the second sealing material.

8. The light emitting diode package according to claim 7, wherein a portion of the light beam is transformed into a second light having a different color from the light beam by passing through the second phosphor powder of the second sealing layer, and another portion of the light beam is transformed into a first light having a different color from the light beam by passing through the first phosphor powder of the first sealing layer.

9. The light emitting diode package according to claim 8, wherein the first light and the second light are white light.

10. An illuminating device comprising:
a lampshade;
a lamp holder, wherein the lampshade and the lamp holder enclose an accommodating space; and
a light emitting diode package, disposed in the accommodating space, the light emitting diode package comprising:
a transparent substrate having a first surface and a second surface opposite to each other;
at least one LED chip disposed on the first surface of the transparent substrate;
a first sealing layer disposed on the first surface of the transparent substrate and covering the LED chip; and
a second sealing layer disposed on the second surface of the transparent substrate and overlapping with the LED chip in a direction perpendicular to the transparent substrate, wherein the LED chip is used to emit a light beam, and a portion of the light beam exits the LED package by passing through the transparent substrate and the second sealing layer.
